(19) United States
(12) Patent Application Publication
(10) Pub. No.: US 2024/0186370 A1
(43) Pub. Date: Jun. 6, 2024

(54) HETEROGENEOUS SUPERJUNCTION DEVICES

(71) Applicant: Virginia Tech Intellectual Properties, Inc., Blacksburg, VA (US)

(72) Inventors: Yuhao ZHANG, Blacksburg, VA (US); Ming XIAO, Blacksburg, VA (US); Yunwei MA, Blacksburg, VA (US)

(21) Appl. No.: 18/486,883

(22) Filed: Oct. 13, 2023

Related U.S. Application Data
(60) Provisional application No. 63/429,789, filed on Dec. 2, 2022.

(51) Int. Cl. H01L 29/06; H01L 29/78; H01L 29/80; H01L 29/861; H01L 29/872

(52) U.S. Cl. CPC H01L 29/0615; H01L 29/0657; H01L 29/7827; H01L 29/80; H01L 29/8613; H01L 29/872; H01L 29/267

(57) ABSTRACT

A device may include a substrate of a first conductivity type, the first conductivity type being one of a n-type conductivity and a p-type conductivity, the substrate having a base surface. A device may include a first terminal coupled with the base surface of the substrate, a first semiconductor region disposed over the substrate, the substrate positioned between the first semiconductor region and the first terminal, the first semiconductor region including a top surface, which defines a plurality of trenches having sidewalls, the plurality of trenches separated by a plurality of pillars, the first semiconductor region formed of a first material with the first conductivity type, a second semiconductor region disposed over the sidewalls of the first semiconductor region to form a superjunction with the first semiconductor region, the second semiconductor region formed of a second material different from the first material and having a second conductivity type.

### CROSS REFERENCE TO RELATED APPLICATIONS

This application claims priority to U.S. Provisional Application No. 63/429,789, filed Dec. 2, 2022, entitled “Heterogeneous Super Junction Devices,” which is incorporated by reference herein in its entirety.

### STATEMENT REGARDING FEDERALLY SPONSORED RESEARCH OR DEVELOPMENT

This invention was made with government support under grant number N00014-21-1-2183, awarded by the Office of Naval Research. The government has certain rights in the invention.

### TECHNICAL FIELD

This disclosure relates to the semiconductor devices, and in particular to heterogeneous superjunction devices.

### DESCRIPTION OF THE RELATED TECHNOLOGY

Performance of one-dimensional, unipolar power devices can be limited by the aspect that the specific on-resistance (R_{ON,SP}) increases with the square of the breakdown voltage (BV). Thus, even when these devices achieve high breakdown voltages, the accompanying high specific on-resistance can negatively impact the performance of these devices. In some instances, vertical superjunction devices can be presented as an alternative. For example, some vertical superjunction devise can have their specific on-resistance that can be lower than the on-dimensional unipolar devices, and can increase only linearly with the breakdown voltage.

### SUMMARY

In some aspects, the techniques described herein relate to a semiconductor device, including: a substrate of a first conductivity type, the first conductivity type being one of a n-type conductivity and a p-type conductivity, the substrate having a base surface; a first terminal coupled with the base surface of the substrate; a first semiconductor region disposed over the substrate, the substrate positioned between the first semiconductor region and the first terminal, the first semiconductor region including a top surface, which defines a plurality of trenches having sidewalls, the plurality of trenches separated by a plurality of pillars, the first semiconductor region formed of a first material with the first conductivity type; a second semiconductor region disposed over the sidewalls of the first semiconductor region to form a superjunction with the first semiconductor region, the second semiconductor region formed of a second material different from the first material and having a second conductivity type, the second conductivity type being the other of the n-type conductivity and p-type conductivity, the second semiconductor material having a product of critical electrical field and permittivity, where the product is greater than that of the first semiconductor region; and a second terminal positioned over the first semiconductor region, the second terminal in ohmic electrical contact with the second semiconductor region.

In some aspects, the techniques described herein relate to a semiconductor device, wherein a first product is a product of an effective width of the plurality of pillars and a first acceptor/donor concentration of the first semiconductor region, wherein a second product is a product of an effective width of the second semiconductor region and a second acceptor/donor concentration of the second semiconductor region, and wherein the first product is greater than or less than the second product by no more than 30% of the second product.

In some aspects, the techniques described herein relate to a semiconductor device, wherein the second terminal forms a Schottky contact with the first semiconductor region.

In some aspects, the techniques described herein relate to a semiconductor device, wherein the second semiconductor region completely fills the plurality of trenches in the first semiconductor region.

In some aspects, the techniques described herein relate to a semiconductor device, further including a third semiconductor region in contact with both the second terminal and the second semiconductor region, the third semiconductor region formed of the same material as the second semiconductor region and having a doping concentration that is greater than that of the second semiconductor region.

In some aspects, the techniques described herein relate to a semiconductor device, further including a diode forming semiconductor region disposed over the first semiconductor region and having the second conductivity type, the diode forming semiconductor region forming a diode junction with the first semiconductor region.

In some aspects, the techniques described herein relate to a semiconductor device, wherein the diode forming semiconductor region is formed of the same material as the first semiconductor region.

In some aspects, the techniques described herein relate to a semiconductor device, wherein the second semiconductor region completely fills the plurality of trenches in the first semiconductor region.

In some aspects, the techniques described herein relate to a semiconductor device, further including an ohmic contact forming metal region positioned between the second terminal and the diode forming semiconductor region, the first ohmic contact forming semiconductor region having a second conductivity type.

In some aspects, the techniques described herein relate to a semiconductor device further including an ohmic contact forming semiconductor region positioned between the second terminal and the second semiconductor region, the second ohmic contact forming semiconductor region having the second conductivity type.

In some aspects, the techniques described herein relate to a semiconductor device, wherein the semiconductor device is a metal oxide semiconductor field effect transistor (MOSFET), the first terminal is a drain terminal, and the second terminal is a source terminal, the semiconductor device further including: a source semiconductor region disposed over the first semiconductor region, wherein the source terminal is in electrical contact with both the source semiconductor region and the second semiconductor region; and a gate terminal and a dielectric material disposed over the first semiconductor region.

In some aspects, the techniques described herein relate to a semiconductor device, wherein the second semiconductor region completely fills the plurality of trenches in the first semiconductor region.

In some aspects, the techniques described herein relate to a semiconductor device, further including an ohmic contact forming semiconductor region positioned between the source terminal and the second semiconductor region, the ohmic contact forming semiconductor region having the second conductivity type.

In some aspects, the techniques described herein relate to a semiconductor device, wherein the ohmic contact forming semiconductor region is formed of the same material as the second semiconductor region.

In some aspects, the techniques described herein relate to a semiconductor device, wherein the semiconductor device is a junction field effect transistor (JFET), the first terminal is a drain terminal, and the second terminal is a source terminal, the semiconductor device further including: a gate terminal; and a gate semiconductor region disposed between the gate terminal and the first semiconductor region, the gate semiconductor region formed of the first material and having the second conductivity type, wherein the source terminal is in electrical contact with both the first semiconductor region and the second semiconductor region.

In some aspects, the techniques described herein relate to a semiconductor device, wherein the second semiconductor region completely fills the plurality of trenches in the first semiconductor region.

In some aspects, the techniques described herein relate to a semiconductor device, further including an ohmic contact forming semiconductor region positioned between the source terminal and the second semiconductor region, the ohmic contact forming semiconductor region having the second conductivity type.

In some aspects, the techniques described herein relate to a semiconductor device, wherein the ohmic contact forming semiconductor region is formed of the same material as the second semiconductor region.

### BRIEF DESCRIPTION OF THE DRAWINGS

FIG. 1 shows a cross-sectional sideview of a first example superjunction pn diode.

FIG. 2 depicts a cross sectional sideview of a second example superjunction pn diode.

FIG. 3 depicts a cross-sectional sideview of a third example superjunction pn diode.

FIG. 4 depicts a cross-sectional side view of a first example superjunction Schottky diode.

FIG. 5 depicts a cross-sectional sideview of a second example superjunction Schottky diode.

FIG. 6 depicts a cross-sectional sideview of a third example superjunction Schottky diode.

FIG. 7 depicts a cross-sectional view of a first example superjunction metal-oxide semiconductor field effect transistor (MOSFET).

FIG. 8 shows a cross-sectional sideview of a second example superjunction MOSFET.

FIG. 9 shows a cross-sectional sideview of a third example superjunction MOSFET.

FIG. 10 shows a cross-sectional sideview of a first example superjunction junction field effect transistor (JFET).

FIG. 11 shows a cross-sectional sideview of a second example superjunction JFET.

FIG. 12 shows a cross-sectional sideview of a third example superjunction JFET.

Like reference numbers and designations in the various drawings indicate like elements.

### DETAILED DESCRIPTION

The various concepts introduced above and discussed in greater detail below may be implemented in any of numerous ways, as the described concepts are not limited to any particular manner of implementation. Examples of specific implementations and applications are provided primarily for illustrative purposes.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

Prior to describing the various aspects of the present disclosure, the following definitions are provided and should be used unless otherwise indicated. Additional terms may be defined elsewhere in the present disclosure.

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used herein, the term “and/or” includes any and all combinations of one or more of the associated listed items. Expressions such as “at least one of,” when preceding a list of elements, modify the entire list of elements and do not modify the individual elements of the list.

As used in the specification and the appended claims, the singular forms “a,” “an” and “the” include plural referents unless the context clearly dictates otherwise. Thus, for example, reference to “a proton beam degrader,” “a degrader foil,” or “a conduit,” includes, but is not limited to, two or more such proton beam degraders, degrader foils, or conduits, and the like.

The various concepts introduced above and discussed in greater detail below may be implemented in any of numerous ways, as the described concepts are not limited to any particular manner of implementation. Examples of specific implementations and applications are provided primarily for illustrative purposes.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e. one atmosphere).

Performance of one-dimensional, unipolar power devices can be limited by the aspect that the specific on-resistance (R_{ON,SP}) increases with the square of the breakdown voltage (BV). Thus, even when these devices achieve high breakdown voltages, the accompanying high specific on-resistance can negatively impact the performance of these devices. In some instances, vertical superjunction devices can be presented as an alternative. For example, some vertical superjunction devise can have their specific on-resistance that can be lower than the on-dimensional unipolar devices, and can increase only linearly with the breakdown voltage. However, the performance of the vertical superjunction devices still suffers from peak electric fields in the drift region, which limits the breakdown voltage of these devices.

One or more devices discussed below utilize structures that reduce the peak electric field in the drift region, thereby reducing the risk of surface premature breakdown of the device. As a result, the breakdown voltage of the devices can be improved.

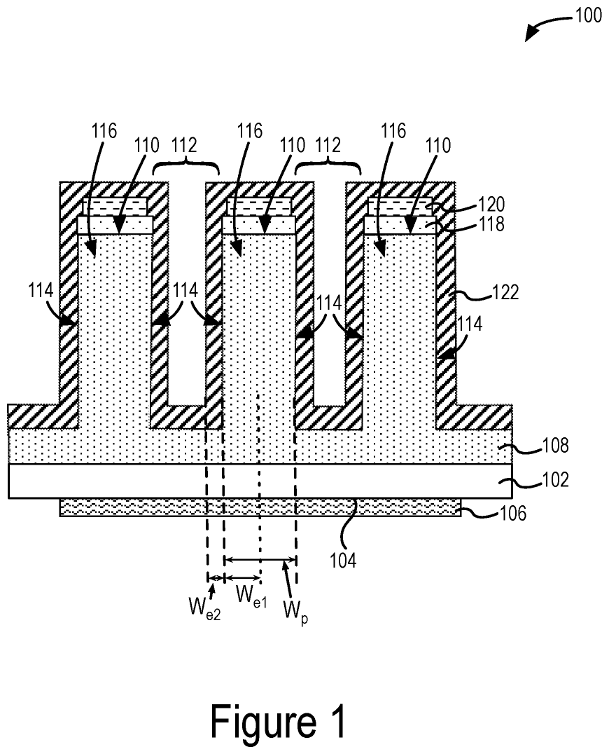

FIG. 1 shows cross-sectional sideview of a first example superjunction pn diode 100. The first example superjunction pn diode 100 includes a substrate 102 of a first conductivity type, where the first conductivity type can be one of a n-type conductivity and a p-type conductivity. The substrate 102 can include a base surface 104 on one of the sides of the substrate 102. A first terminal 106 can be coupled with the base surface 104 of the substrate 102. The first terminal 106 can, for example be a cathode. The first terminal 106 can include materials such as, for example, titanium, aluminum, nickel, gold, and other suitable metals. In some instances, the material choice can depend upon the material of the substrate 102 to ensure that the substrate 102 and the first terminal 106 form an ohmic contact.

The first example superjunction pn diode 100 includes a first semiconductor region 108 disposed over the substrate 102, such that the substrate 102 is positioned between the first semiconductor region 108 and the first terminal 106. For example, the first semiconductor region 108 is in direct contact with the substrate 102. In some instances, the substrate 102 and the first semiconductor region 108 can be formed of the same material and of the same conductivity type. For example, if the substrate 102 is formed of an n-type (p-type) gallium nitride, the first semiconductor region 108 can also be formed of an n-type (p-type) gallium nitride. In some examples, the doping concentration of the substrate 102 can be greater than the doping concentration of the first semiconductor region 108. In some other instances, the substrate 102 can be formed of a material that is different from the material used to form the first semiconductor region 108.

The first semiconductor region 108 can include a top surface 110, which defines a plurality of trenches 112 having sidewalls 114. The plurality of trenches 112 can be separated by a plurality of pillars 116. Each of the plurality of trenches 112 can have the same depth, however, in some instances, one or more of the plurality of trenches 112 can have depths that are different from other of the plurality of trenches 112. While FIG. 1 shows only three pillars and two trenches, this is only an example, and that the first example superjunction pn diode 100 can include additional trenches separated by pillars. In some examples, the width of the plurality of pillars 116 can be substantially uniform.

The first example superjunction pn diode 100 can include a diode forming semiconductor region 118 disposed over the top surface 110 of the first semiconductor region 108. The diode forming semiconductor region 118 can have a conductivity type that is different from the conductivity type of the first semiconductor region 108. For example, if the first semiconductor region 108 has a first conductivity type (n-type/p-type), the diode forming semiconductor region 118 can have a second conductivity type (p-type/n-type). The diode forming semiconductor region 118 can form a diode (pn) junction with the first semiconductor region 108 at the interface of the diode forming semiconductor region 118 and the first semiconductor region 108. In some examples, the diode forming semiconductor region 118 can be formed of the same material as the first semiconductor region 108, albeit with different conductivity type. For example, if the first semiconductor region 108 is formed of gallium nitride, the diode forming semiconductor region 118 can also be formed of gallium nitride.

A second terminal 120 can be positioned over the first semiconductor region 108. In the example shown in FIG. 1, the diode forming semiconductor region 118 can be positioned between the first semiconductor region 108 and the second terminal 120. The second terminal 120 can form an ohmic contact with the diode forming semiconductor region 118. The second terminal 120 can, in some examples, be referred to as an anode, and can include materials that are able to form an ohmic contact with the material of the diode forming semiconductor region 118. While not shown in the cross-sectional view of FIG. 1, the second terminal 120 on each of the plurality of pillars 116 are electrically coupled with each other. Examples of the second terminal 120 can include metals such as titanium, aluminum, nickel, gold, and other suitable conducting materials.

The first example superjunction pn diode 100 also includes a second semiconductor region 122 disposed over the sidewalls 114 of the first semiconductor region 108 to form a superjunction with the first semiconductor region 108. The second semiconductor region 122 can be deposited over the sidewalls 114 such that the second semiconductor region 122 is in contact with the first semiconductor region 108. The second semiconductor region 122 also can cover the sides of the diode forming semiconductor region 118 and the sides and top surfaces of the second terminal 120. The second semiconductor region 122 can have a substantially uniform thickness W2 over the sidewalls 114. The second semiconductor region 122 can also make contact with the diode forming semiconductor region 118 and the second terminal 120. The second terminal 120 can form an ohmic contact with the second semiconductor region 122. That is the second terminal 120 can form an ohmic contact with both the diode forming semiconductor region 118 and the second semiconductor region 122. In some instances, based on the materials used to form the diode forming semiconductor region 118 and the second semiconductor region 122, a single metal or alloy can be selected that can form ohmic contacts with these materials. In some other instances, additional interface materials can be utilized to ensure the formation of the ohmic contacts between the second terminal 120 and the second semiconductor region 122, and the second terminal 120 and the diode forming semiconductor region 118.

The second semiconductor region 122 can be formed of materials that are different from the materials used to form the first semiconductor region 108. For example, the second semiconductor region 122 can be a nickel oxide (NiO) material while the first semiconductor region 108 can be a gallium nitride material. Of course, other materials can also be used such as, for example, silicon carbide, diamond, aluminum nitride, gallium oxide, copper oxide, etc. The second semiconductor region 122 can have a conductivity type that is different from the conductivity type of the first semiconductor region 108. For example, if the first semiconductor region 108 is of the first conductivity type (n-type/p-type), the second semiconductor region 122 can be of the second conductivity type (p-type/n-type). The second semiconductor region 122, however, can be of the same conductivity type as the diode forming semiconductor region 118, albeit formed of different material than the diode forming semiconductor region 118.

The first semiconductor region 108 and the second semiconductor region 122 can have respective critical electric field values and permittivity values. The critical electric field of a semiconductor material can refer to a maximum electric field strength that the semiconductor material can withstand before going into avalanche breakdown. In some examples, a product of the critical electric field and permittivity of the second semiconductor region 122 can be greater than the product of the critical electric field and permittivity of the first semiconductor region 108.

The dimensions and the nature of the materials of the first semiconductor region 108 and the second semiconductor region 122 can be selected to maintain a charge balance between the first semiconductor region 108 and the second semiconductor region 122. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 1, the effective width Wₑ₁, of the first semiconductor region 108 can be half the average width Wₚ of the plurality of pillars 116, and the effective width Wₑ₂ of the second semiconductor region 122 can be the average thickness of the second semiconductor region 122 over the sidewalls 114 of the first semiconductor region 108. In some instances, the first product P₁ can be no greater or less than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device.

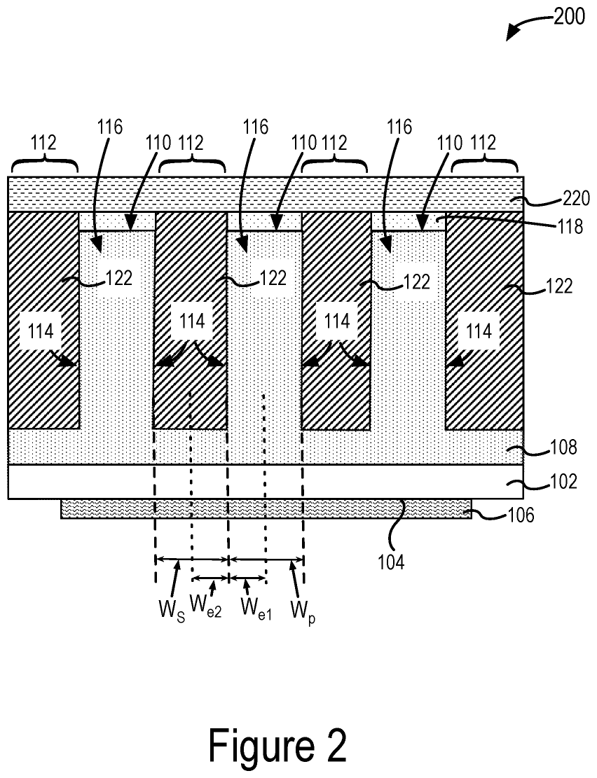

FIG. 2 depicts a cross sectional sideview of a second example superjunction pn diode 200. The second example superjunction pn diode 200 is similar to the first example superjunction pn diode 100 discussed above in relation to FIG. 1. However, unlike the second semiconductor region 122 in the first example superjunction pn diode 100, the second semiconductor region 122 in the second example superjunction pn diode 200 substantially fills the plurality of trenches 112. For example, as shown in FIG. 1, the second semiconductor region 122 deposited on one sidewalls 114 is spaced apart from the second semiconductor region 122 deposited on the opposing sidewalls 114 in the same trench of the plurality of trenches 112. In contrast, in the second example superjunction pn diode 200 shown in FIG. 2, the second semiconductor region 122 on one sidewall is not spaced apart from the second semiconductor region 122 deposited on the opposing sidewall. Instead, the second semiconductor region 122 substantially fills the plurality of trenches 112 such that the plurality of trenches 112 substantially fills the space between two opposing sidewalls within the same trench of the plurality of trenches 112. Similar to the first example superjunction pn diode 100, the second example superjunction pn diode 200 includes the diode forming semiconductor region 118 positioned over the top surface 110 of the first semiconductor region 108 at the plurality of pillars 116.

The second example superjunction pn diode 200 includes a second terminal 220 that makes ohmic contact with both the diode forming semiconductor region 118 and the second semiconductor region 122. While FIG. 2 shows the second terminal 220 completely covering the second semiconductor region 122 and the diode forming semiconductor region 118, this is only an example, and that the configuration of the second terminal 220 can be similar to the configuration of the second terminal 120 shown in FIG. 1.

As discussed above in relation to the first example superjunction pn diode 100, the dimensions and the nature of the materials of the first semiconductor region 108 and the second semiconductor region 122 in the second example superjunction pn diode 200 can be selected to maintain a charge balance between the first semiconductor region 108 and the second semiconductor region 122. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 2, the effective width Wₑ₁, of the first semiconductor region 108 can be half the average width Wₚ of the plurality of pillars 116, and the effective width Wₑ₂ of the second semiconductor region 122 can be half the average width of the second semiconductor region 122 between the sidewalls 114 of the first semiconductor region 108. The average width of the second semiconductor region 122 between the sidewalls 114 can be equal to the average distance between opposing sidewalls 114 or an average width W_{S} of the plurality of trenches 112. As such, the effective width Wₑ₂ of the second semiconductor region 122 can be equal to W_{S}/2. In some instances, the first product P₁ can greater than or less than the second product by no more than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

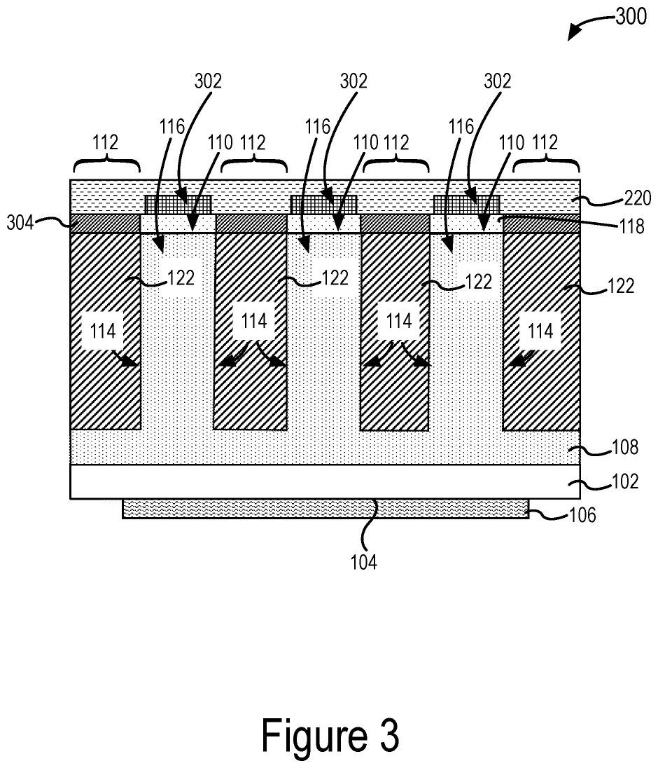

FIG. 3 depicts a cross-sectional sideview of a third example superjunction pn diode 300. The third example superjunction pn diode 300 is similar to the first example superjunction pn diode 100 and the second example superjunction pn diode 200 discussed above in relation to FIGS. 1 and 2. In particular, the third example superjunction pn diode 300 is similar to the second example superjunction pn diode 200 in that the second semiconductor region 122 in third example superjunction pn diode 300, like the second semiconductor region 122 in second example superjunction pn diode 200, completely fills the plurality of trenches 112. The third example superjunction pn diode 300 includes ohmic contact forming regions that enable the formation of ohmic contacts between the second terminal 220 and the diode forming semiconductor region 118 and the second terminal 220 and the second semiconductor region 122. For example, the third example superjunction pn diode 300 includes an ohmic contact forming metal region 302 positioned between the second terminal 220 and the diode forming semiconductor region 118, and includes an ohmic contact forming semiconductor region 304 positioned between the second terminal 220 and the second semiconductor region 122. The ohmic contact forming metal region 302 can be a metal that allows the formation of an ohmic contact between the diode forming semiconductor region 118 and the second terminal 220. As an example, if the second terminal 220 includes Ni, the ohmic contact forming metal region 302 can include Ni or Au or both. In instances where the diode forming semiconductor region 118 can directly form an ohmic contact with the second terminal 220, the ohmic contact forming metal region 302 may not be needed. The conductivity type of the ohmic contact forming semiconductor region 304 can be the same as the conductivity type of the second semiconductor region 122. For example, if the conductivity type of the second semiconductor region 122 is p-type (n-type) then the conductivity type of the ohmic contact forming semiconductor region 304 is also p-type (n-type). In some instances, the ohmic contact forming semiconductor region 304 can be formed of the same materials as the second semiconductor region 122. In some examples, the ohmic contact forming semiconductor region 304 can have a doping concentration that is greater than the doping concentration of the second semiconductor region 122.

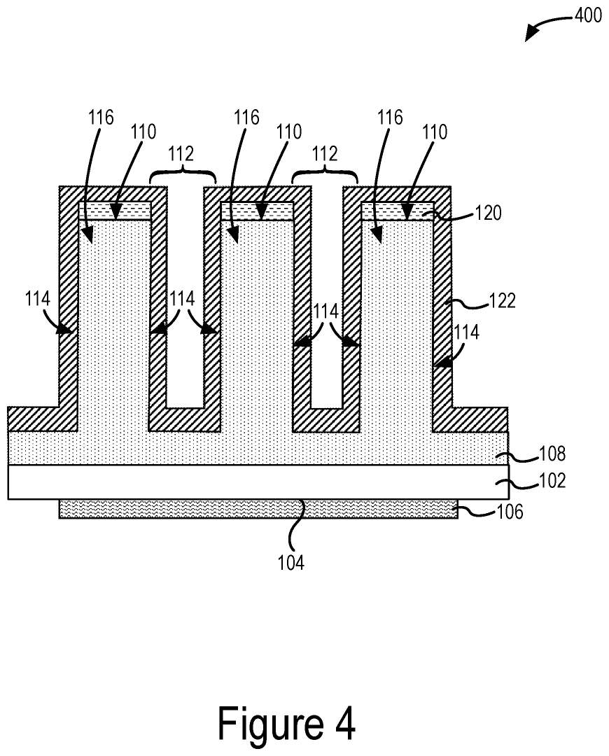

FIG. 4 depicts a cross-sectional side view of a first example superjunction Schottky diode 400. The first example superjunction Schottky diode 400 is similar to the first example superjunction pn diode 100 discussed above in relation to FIG. 1. However, unlike the first example superjunction pn diode 100, which included a diode forming semiconductor region 118 over the top surface 110 of the first semiconductor region 108, the first example superjunction Schottky diode 400 is devoid of such a diode forming region. Instead, the second terminal 120 makes a Schottky contact with the first semiconductor region 108, thereby forming a Schottky diode. Similar to the first example superjunction pn diode 100, the first example superjunction Schottky diode 400 also includes the second semiconductor region 122 disposed on the sidewalls 114 of the first semiconductor region 108. The second semiconductor region 122 also cover the side and top surfaces of the second terminal 120. The second semiconductor region 122 does not completely fill the plurality of trenches 112 but is instead disposed on the sidewalls 114 with an average thickness. As discussed above in relation to the first example superjunction pn diode 100 shown in FIG. 1, the second semiconductor region 122 can maintain a charge balance with the first semiconductor region 108. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 4, the effective width Wₑ₁, of the first semiconductor region 108 can be half the average width of the plurality of pillars 116, and the effective width Wₑ₂ of the second semiconductor region 122 can be the average thickness of the second semiconductor region 122 over the sidewalls 114 of the first semiconductor region 108. In some instances, the first product P₁ can be greater than or less than the second product by no more than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

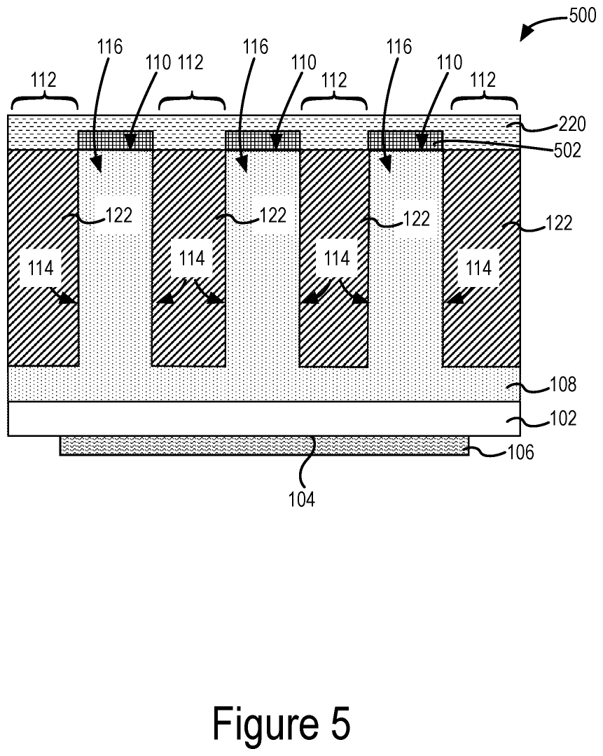

FIG. 5 depicts a cross-sectional sideview of a second example superjunction Schottky diode 500. The second example superjunction Schottky diode 500 is similar to the first example superjunction Schottky diode 400 discussed above in relation to FIG. 4. However, unlike the first example superjunction Schottky diode 400 in which the second semiconductor region 122 covers the sidewalls 114 without fully filing the plurality of trenches 112, in the second example superjunction Schottky diode 500 the second semiconductor region 122 completely fills the plurality of trenches 112. This is similar to the second example superjunction pn diode 200 discussed above in relation to FIG. 2. The second example superjunction Schottky diode 500 can include a Schottky contact forming region 502 that facilitates the formation of a Schottky contact between the first semiconductor region 108 and the second terminal 220. The second terminal 220 forms an ohmic contact with the second semiconductor region 122.

As discussed above in relation to the first example superjunction Schottky diode 400, the dimensions and the nature of the materials of the first semiconductor region 108 and the second semiconductor region 122 in the second example superjunction Schottky diode 500 can be selected to maintain a charge balance between the first semiconductor region 108 and the second semiconductor region 122. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 5, the effective width Wei, of the first semiconductor region 108 can be half the average width Wₚ of the plurality of pillars 116, and the effective width Wₑ₂ of the second semiconductor region 122 can be half the average width of the second semiconductor region 122 between the sidewalls 114 of the first semiconductor region 108. The average width of the second semiconductor region 122 between the sidewalls 114 can be equal to the average distance between opposing sidewalls 114 or an average width W_{S} of the plurality of trenches 112. As such, the effective width Wₑ₂ of the second semiconductor region 122 can be equal to W_{S}/2. In some instances, the first product P₁ can be no greater or less than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

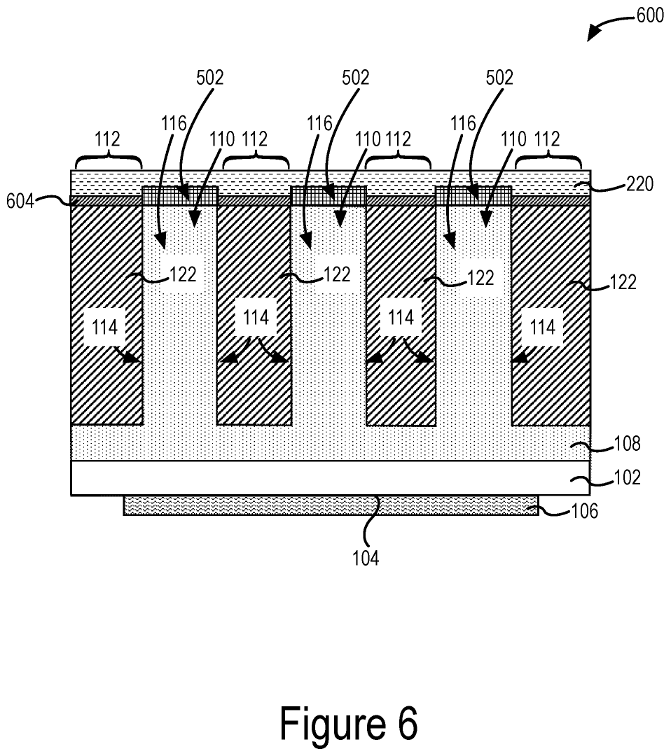

FIG. 6 depicts a cross-sectional sideview of a third example superjunction Schottky diode 600. The third example superjunction Schottky diode 600 is similar to the second example superjunction Schottky diode 500 discussed above in relation to FIG. 5. However, the third example superjunction Schottky diode 600 additionally includes a third semiconductor region 604 that is contact with both the second terminal 220 and the second semiconductor region 122. The third semiconductor region 604 can be formed of the same material as the second semiconductor region 122 and can have a doping concentration that is greater than that of the second semiconductor region 122. The third semiconductor region 604 can help improve the ohmic contact between the second semiconductor region 122 and the second terminal 220.

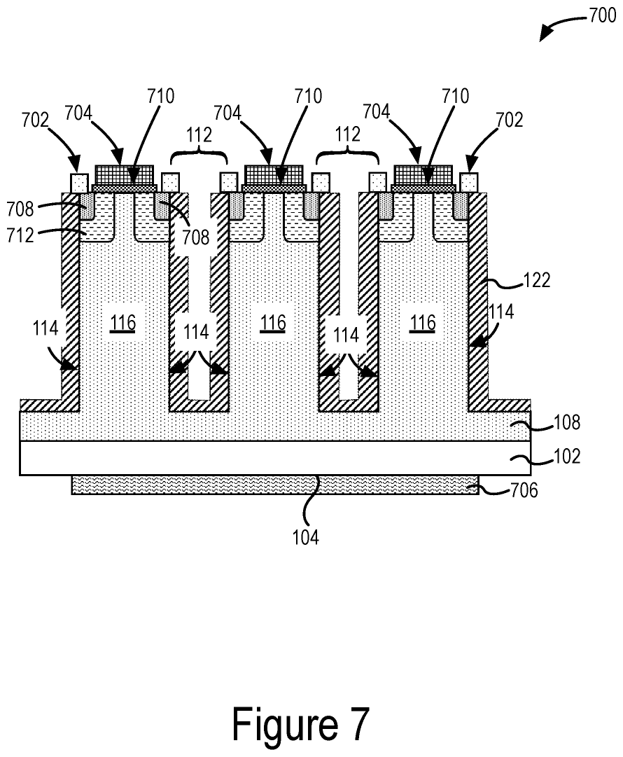

FIG. 7 depicts a cross-sectional view of a first example superjunction metal-oxide semiconductor field effect transistor 700. The first example superjunction MOSFET 700 includes a substrate 102 and a first semiconductor region 108 similar to that described above in relation to FIGS. 1-6. The first example superjunction MOSFET 700 also includes a plurality of pillars 116 and a plurality of trenches 112 similar to that described above in relation to FIGS. 1-6. Further, the first example superjunction MOSFET 700 includes a second semiconductor region 122 disposed over the sidewalls 114 of the plurality of pillars 116 of first semiconductor region 108. It should be noted that similar to the first example superjunction pn diode 100, the second semiconductor region 122 in the first example superjunction MOSFET 700 does not completely fill the plurality of trenches 112. Instead, the second semiconductor region 122 on opposing sidewalls 114 are spaced apart.

The first example superjunction MOSFET 700 includes a drain terminal 706 (“the first terminal”) coupled with the base surface 104 of the substrate 102. The first example superjunction MOSFET 700 can also include a source semiconductor region 708 disposed over the first semiconductor region 108. As shown in FIG. 7, the source semiconductor region 708 forms a portion of the sidewall 114 and a portion of a top surface of the plurality of pillars 116. The source semiconductor region 708 is in partial contact with the second semiconductor region 122 that is disposed over the sidewalls 114. The first example superjunction MOSFET 700 further includes a source terminal 702 disposed over the top surface of the plurality of pillars 116. The source terminal 702 is positioned such that the source terminal 702 is in electrical contact with both the source semiconductor region 708 and the second semiconductor region 122. In particular, the source terminal 702 can form an ohmic contact with the second semiconductor region 122. The source semiconductor region 708 can be of the same material as the first semiconductor region 108, have the same conductivity type as the first semiconductor region 108 and have a higher doping concentration than that of the first semiconductor region 108. The first example superjunction MOSFET 700 further includes an interface region 712 that separates the source semiconductor region 708 from the first semiconductor region 108. The interface region 712 can be of the same material as the first semiconductor region 108 and the source semiconductor region 708, and have a conductivity type that is different from that of the first semiconductor region 108 and the source semiconductor region 708. For example, if the first semiconductor region 108 and the source semiconductor region 708 have a first conductivity type (n-type/p-type), then the interface region 712 can have a second conductivity type (p-type/n-type). A portion of the interface region 712 can form a portion of the sidewall 114 and a portion of the top surface of the pillars 116.

The first example superjunction MOSFET 700 can include a gate terminal 704 and a dielectric material 710 disposed over the first semiconductor region 108. In particular, the gate terminal 704 and the dielectric material 710 are positioned over a top surface of the plurality of pillars 116. The dielectric material 710 is positioned between the first semiconductor region 108 and the gate terminal 704. The dielectric material 710 covers at least a portion of the interface region 712 on the top surface of the pillars 116.

The second semiconductor region 122 can maintain a charge balance with the first semiconductor region 108. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 7, the effective width Wₑ₁, of the first semiconductor region 108 can be half the average width Wₚ of the plurality of pillars 116, and the effective width Wₑ₂ of the second semiconductor region 122 can be the average thickness of the second semiconductor region 122 over the sidewalls 114 of the first semiconductor region 108. In some instances, the first product P₁ can be no greater or less than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

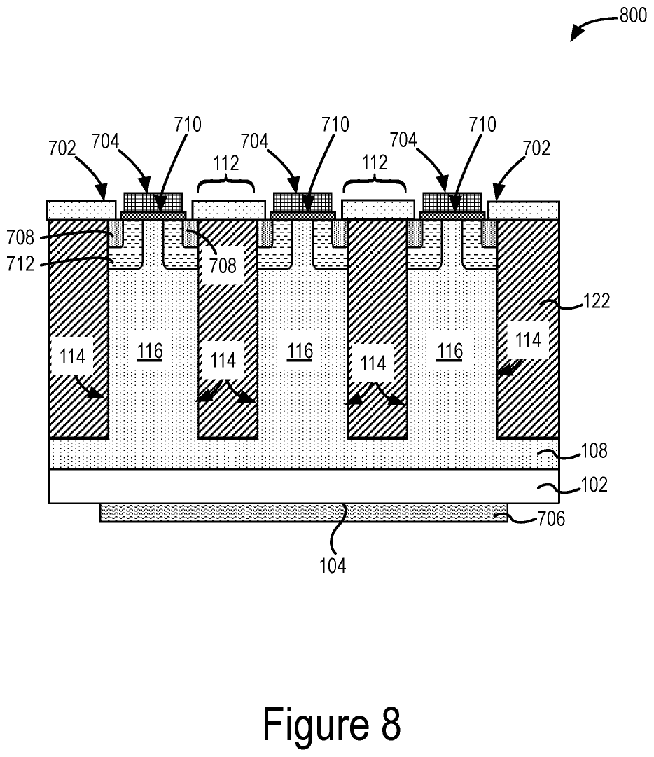

FIG. 8 shows a cross-sectional sideview of a second example superjunction MOSFET 800. The second example superjunction MOSFET 800 is similar to the first example superjunction MOSFET 700 discussed above in relation to FIG. 7. However, unlike the first example superjunction MOSFET 700, where the second semiconductor region 122 does not completely fill the plurality of trenches 112, the second semiconductor region 122 in the second example superjunction MOSFET 800 completely fills the plurality of trenches 112. The dimensions and the nature of the materials of the first semiconductor region 108 and the second semiconductor region 122 in the second example superjunction MOSFET 800 can be selected to maintain a charge balance between the first semiconductor region 108 and the second semiconductor region 122. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 8, the effective width Wₑ₁, of the first semiconductor region 108 can be half the average width Wₚ of the plurality of pillars 116, and the effective width Wₑ₂ of the second semiconductor region 122 can be half the average width of the second semiconductor region 122 between the sidewalls 114 of the first semiconductor region 108. The average width of the second semiconductor region 122 between the sidewalls 114 can be equal to the average distance between opposing sidewalls 114 or an average width W_{S} of the plurality of trenches 112. As such, the effective width Wₑ₂ of the second semiconductor region 122 can be equal to W_{S}/2. In some instances, the first product P₁ can be greater than or less than the second product by no more than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

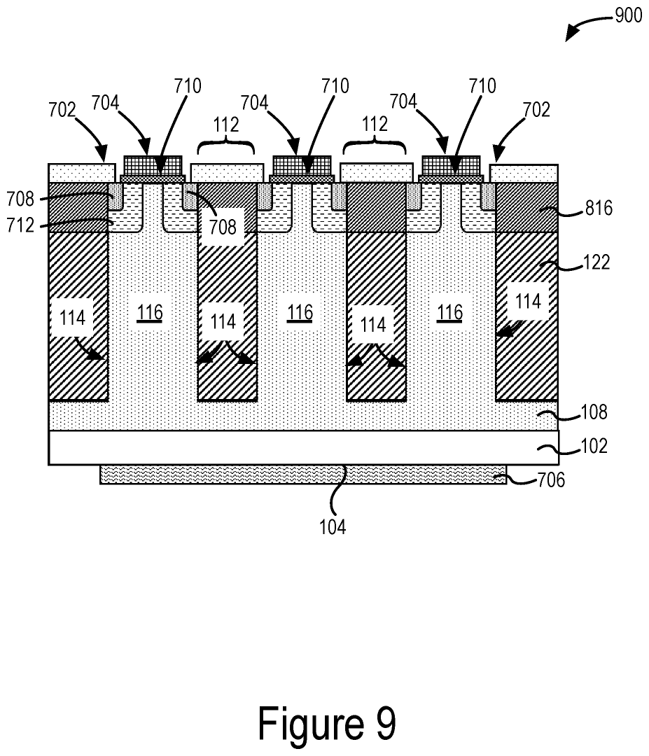

FIG. 9 shows a cross-sectional sideview of a third example superjunction MOSFET 900. The third example superjunction MOSFET 900 is similar to the second example superjunction MOSFET 800 discussed above in relation to FIG. 8 in that the second semiconductor region 122 completely fills the plurality of trenches 112. However, the third example superjunction MOSFET 900 additionally includes an ohmic contact forming semiconductor region 816 positioned between the source terminal 702 and the second semiconductor region 122. The ohmic contact forming semiconductor region 816 can have the same conductivity type as the second semiconductor region 122. For example, if the second semiconductor region 122 is of the n-type (p-type) conductivity, the ohmic contact forming semiconductor region 816 is also of the n-type (p-type) conductivity. The ohmic contact forming semiconductor region 816 can help improve the ohmic contact between the source terminal 702 and the second semiconductor region 122.

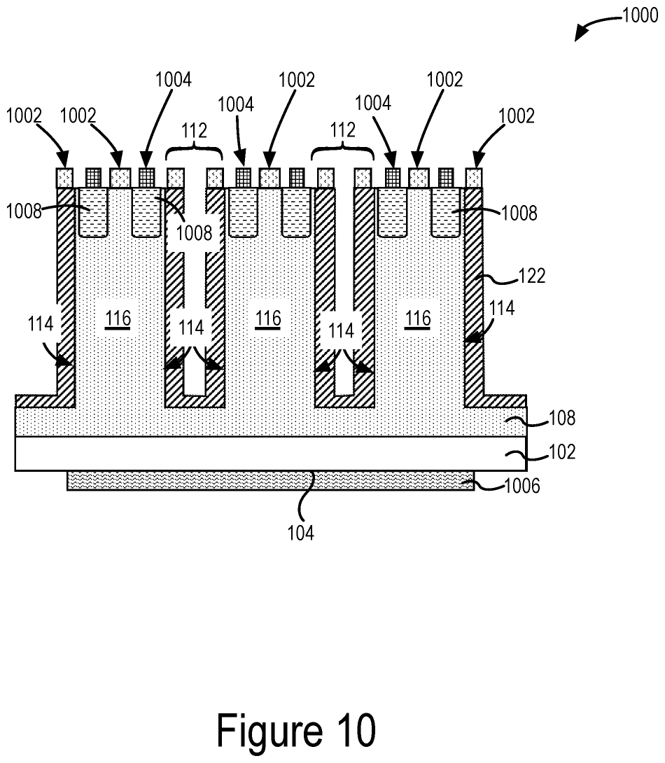

FIG. 10 shows a cross-sectional sideview of a first example superjunction junction field effect transistor (JFET) 1000. The first example superjunction junction field effect transistor 1000 includes a drain terminal 1006 (“the first terminal”) coupled with the base surface 104 of the substrate 102. The first example superjunction junction field effect transistor 1000 also includes a source terminal 1002 that is disposed over the first semiconductor region 108, in particular over the top surface of the plurality of pillars 116. In the example shown in FIG. 10, the source terminal 1002 can have three portions disposed over each pillar 116. While not shown in FIG. 10, all portions of the source terminal 1002 are electrically coupled together. The source terminal 1002 can be in electrical contact with both the first semiconductor region 108 and the second semiconductor region 122. In particular, the source terminal 1002 can form ohmic contacts with both the first semiconductor region 108 and the second semiconductor region 122. The first example superjunction junction field effect transistor 1000 also includes a gate terminal 1004. In the example shown in FIG. 10, the gate terminal 1004 has two portion per pillar 116. The number of portions of the source terminal 1002 and the gate terminal 1004 can vary. For example, there may be only one source terminal portion and only one gate terminal portion per pillar 116. A gate semiconductor region 1008 is disposed between the gate terminal 1004 and the first semiconductor region 108. In the example shown in FIG. 10, the gate semiconductor region 1008 forms a portion of the top surface of the pillar 116, where the gate semiconductor region 1008 makes contact with the gate terminal 1004. The gate semiconductor region 1008 can be formed of the same material as the first semiconductor region 108 and can have a conduction type that is different from the conduction type of the first semiconductor region 108. For example, if the conduction type of the first semiconductor region 108 is n-type (p-type), the conduction type of the gate semiconductor region 1008 can be p-type (n-type) as well. The second semiconductor region 122, similar to that discussed above in relation to the first example superjunction MOSFET 700 shown in FIG. 7, is disposed over the sidewalls 114 of the plurality of pillars 116 of the first semiconductor region 108. The second semiconductor region 122 do not completely fill the plurality of trenches 112, and the second semiconductor region 122 on opposing sidewalls 114 are spaced apart.

The second semiconductor region 122 can maintain a charge balance with the first semiconductor region 108. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 10, the effective width Wₑ₁ of the first semiconductor region 108 can be half the average width Wₚ of the plurality of pillars 116, and the effective width Wₑ₂ of the second semiconductor region 122 can be the average thickness of the second semiconductor region 122 over the sidewalls 114 of the first semiconductor region 108. In some instances, the first product P₁ can be greater than or less than the second product by no more than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

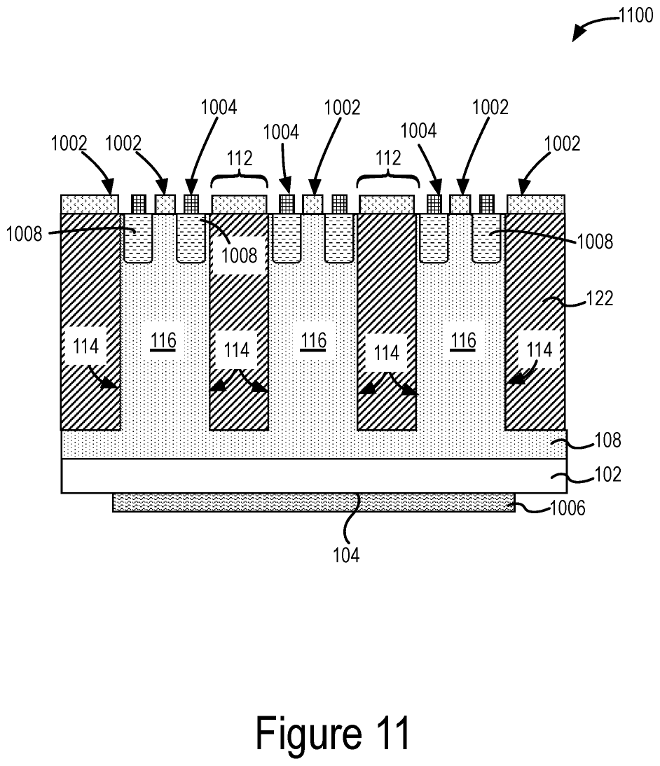

FIG. 11 shows a cross-sectional sideview of a second example superjunction junction field effect transistor 1100. The second example superjunction junction field effect transistor 1100 is similar to the first example superjunction junction field effect transistor 1000 discussed above in relation to FIG. 10. However, unlike the first example superjunction junction field effect transistor 1000, where the second semiconductor region 122 that is disposed on the sidewalls 114 does not completely fill the plurality of trenches 112, the second semiconductor region 122 in the second example superjunction junction field effect transistor 1100 completely fills the plurality of trenches 112. The source terminal 1002 is in contact with both the second semiconductor region 122 and the first semiconductor region 108. In particular, the source terminal 1002 forms ohmic contacts with both the second semiconductor region 122 and the first semiconductor region 108.

The dimensions and the nature of the materials of the first semiconductor region 108 and the second semiconductor region 122 in the second example superjunction junction field effect transistor 1100 can be selected to maintain a charge balance between the first semiconductor region 108 and the second semiconductor region 122. For example, a first product P₁ of an effective width Wₑ₁ of the first semiconductor region 108 and the acceptor/donor concentration N₁ of the first semiconductor region 108 can be substantially equal to a second product P₂ of the effective width Wₑ₂ of the second semiconductor region 122 and the acceptor/donor concentration N₂ of the second semiconductor region 122. In the example shown in FIG. 11, the effective width Wₑ₁, of the first semiconductor region 108 can be half the average width Wₚ of the plurality of pillars 116, and the effective width Wₑ₂ of the second semiconductor region 122 can be half the average width of the second semiconductor region 122 between the sidewalls 114 of the first semiconductor region 108. The average width of the second semiconductor region 122 between the sidewalls 114 can be equal to the average distance between opposing sidewalls 114 or an average width W_{S} of the plurality of trenches 112. As such, the effective width Wₑ₂ of the second semiconductor region 122 can be equal to W_{S}/2. In some instances, the first product P₁ can be greater than or less than the second product by no more than 30% of the second product P₂. The inclusion of the second semiconductor region 122 on the sidewalls 114 of the first semiconductor region 108 can reduce peak electric fields within the device. The reduction of the peak electric fields within the device, in turn, improves the breakdown voltage of the device. In some examples, a product of the critical electric field and permittivity of the second semiconductor region 122 can be greater than the product of the critical electric field and permittivity of the first semiconductor region 108.

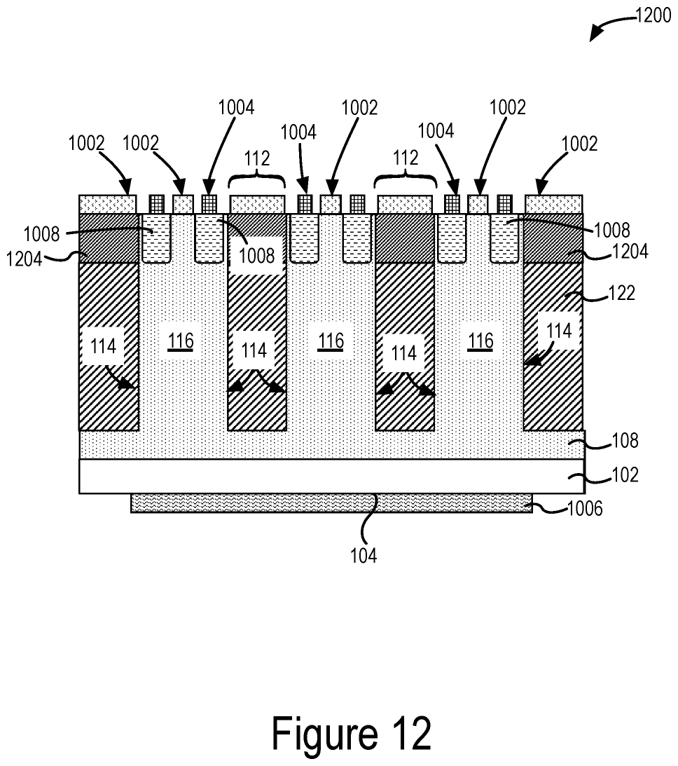

FIG. 12 shows a cross-sectional sideview of a third example superjunction junction field effect transistor 1200. The third example superjunction junction field effect transistor 1200 is similar to the second example superjunction junction field effect transistor 1100 discussed above in relation to FIG. 11. However, the third example superjunction junction field effect transistor 1200 further includes an ohmic contact forming semiconductor region 1204 positioned between the source terminal 1002 and the second semiconductor region 122. The ohmic contact forming semiconductor region 1204 can improve the ohmic contact between the second semiconductor region 122 and the source terminal 1002. The ohmic contact forming semiconductor region 1204 can be formed of the same material as the second semiconductor region 122 but can have doping concentration that is greater than that of the second semiconductor region 122. The ohmic contact forming semiconductor region 1204 can have the same conductivity type as the conductivity type of second semiconductor region 122.

References: All cited references, patent or literature, are incorporated by reference in their entirety. The examples disclosed herein are illustrative and not limiting in nature. Details disclosed with respect to the methods described herein included in one example or embodiment may be applied to other examples and embodiments. Any aspect of the present disclosure that has been described herein may be disclaimed, i.e., exclude from the claimed subject matter whether by proviso or otherwise.
[1] F. Udrea et al., IEEE Trans. Electron Devices, vol. 64, pp. 720, 2017.
[2] X. Zhong et al., in 2016 Int. Symp. Power Semicond. Devices ICs, pp. 231.
[3] T. Masuda et al., in 2018 IEEE Int. Electron Devices Meet., pp. 8.1.
[4] Z. Li et al., IEEE Trans. Electron Devices, vol. 60, pp. 3230, 2013.
[5] M. Xiao et al., IEEE J. Emerg. Sel. Top. Power Electron., vol. 7, pp. 1475, 2019.
[6] A. Nakajima et al., Appl. Phys. Lett., vol. 89, pp. 193501, 2006.
[7] H. Ishida et al., in 2008 IEEE Int. Electron Devices Meet., pp. 1-4.
[8] S.-W. Han et al., IEEE Trans. Electron Devices, vol. 68, pp. 5736, 2021.
[9] A. Nakajima et al, IEEE Electron Device Lett., vol. 32, pp. 542, 2011.
[10] T. Narita et al., J. Appl. Phys., vol. 128, pp. 090901, 2020.
[11] J. A. Spencer et al., Appl. Phys. Rev., vol. 9, pp. 011315, 2022.
[12] Y. Ma et al., Appl. Phys. Lett., vol. 117, pp. 143506, 2020.
[13] M. Xiao et al., in 2020 IEEE Int. Electron Devices Meet., pp. 5.4.
[14] Y. Zhang et al., Appl. Phys. Lett., vol. 111, pp. 163506, 2017.
[15] S. Nandy et al., J. Mater. Sci., vol. 42, pp. 5766, 2007.
[16] J. Sakakibara et al., in 2008 Int. Symp. Power Semicond. Devices Ics, pp. 299.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

What is claimed is:

1. A semiconductor device, comprising:
a substrate of a first conductivity type, the first conductivity type being one of a n-type conductivity and a p-type conductivity, the substrate having a base surface;
a first terminal coupled with the base surface of the substrate;
a first semiconductor region disposed over the substrate, the substrate positioned between the first semiconductor region and the first terminal, the first semiconductor region including a top surface, which defines a plurality of trenches having sidewalls, the plurality of trenches separated by a plurality of pillars, the first semiconductor region formed of a first material with the first conductivity type;
a second semiconductor region disposed over the sidewalls of the first semiconductor region to form a superjunction with the first semiconductor region, the second semiconductor region formed of a second material different from the first material and having a second conductivity type, the second conductivity type being the other of the n-type conductivity and p-type conductivity, the second semiconductor material having a product of critical electrical field and permittivity, where the product is greater than that of the first semiconductor region; and
a second terminal positioned over the first semiconductor region, the second terminal in ohmic electrical contact with the second semiconductor region.

2. The semiconductor device of claim 1, wherein a first product is a product of an effective width of the plurality of pillars and a first acceptor/donor concentration of the first semiconductor region, wherein a second product is a product of an effective width of the second semiconductor region and a second acceptor/donor concentration of the second semiconductor region, and wherein the first product is greater than or less than the second product by no more than 30% of the second product.

3. The semiconductor device of claim 1, wherein the second terminal forms a Schottky contact with the first semiconductor region.

4. The semiconductor device of claim 3, wherein the second semiconductor region completely fills the plurality of trenches in the first semiconductor region.

5. The semiconductor device of claim 4, further comprising a third semiconductor region in contact with both the second terminal and the second semiconductor region, the third semiconductor region formed of the same material as the second semiconductor region and having a doping concentration that is greater than that of the second semiconductor region.

6. The semiconductor device of claim 1, further comprising a diode forming semiconductor region disposed over the first semiconductor region and having the second conductivity type, the diode forming semiconductor region forming a diode junction with the first semiconductor region.

7. The semiconductor device of claim 6, wherein the diode forming semiconductor region is formed of the same material as the first semiconductor region.

8. The semiconductor device of claim 6, wherein the second semiconductor region completely fills the plurality of trenches in the first semiconductor region.

9. The semiconductor device of claim 8, further comprising an ohmic contact forming metal region positioned between the second terminal and the diode forming semiconductor region, the first ohmic contact forming semiconductor region having a second conductivity type.

10. The semiconductor device of claim 8 further comprising an ohmic contact forming semiconductor region positioned between the second terminal and the second semiconductor region, the second ohmic contact forming semiconductor region having the second conductivity type.

11. The semiconductor device of claim 1, wherein the semiconductor device is a metal oxide semiconductor field effect transistor (MOSFET), the first terminal is a drain terminal, and the second terminal is a source terminal, the semiconductor device further comprising:
a source semiconductor region disposed over the first semiconductor region, wherein the source terminal is in electrical contact with both the source semiconductor region and the second semiconductor region; and
a gate terminal and a dielectric material disposed over the first semiconductor region.

12. The semiconductor device of claim 11, wherein the second semiconductor region completely fills the plurality of trenches in the first semiconductor region.

13. The semiconductor device of claim 12, further comprising an ohmic contact forming semiconductor region positioned between the source terminal and the second semiconductor region, the ohmic contact forming semiconductor region having the second conductivity type.

14. The semiconductor device of claim 13, wherein the ohmic contact forming semiconductor region is formed of the same material as the second semiconductor region.

15. The semiconductor device of claim 1, wherein the semiconductor device is a junction field effect transistor (JFET), the first terminal is a drain terminal, and the second terminal is a source terminal, the semiconductor device further comprising:
a gate terminal; and
a gate semiconductor region disposed between the gate terminal and the first semiconductor region, the gate semiconductor region formed of the first material and having the second conductivity type,
wherein the source terminal is in electrical contact with both the first semiconductor region and the second semiconductor region.

16. The semiconductor device of claim 15, wherein the second semiconductor region completely fills the plurality of trenches in the first semiconductor region.

17. The semiconductor device of claim 16, further comprising an ohmic contact forming semiconductor region positioned between the source terminal and the second semiconductor region, the ohmic contact forming semiconductor region having the second conductivity type.

18. The semiconductor device of claim 17, wherein the ohmic contact forming semiconductor region is formed of the same material as the second semiconductor region.
